(19) United States
(12) Patent Application Publication
(10) Pub. No.: US 2022/0178968 A1
(43) Pub. Date: Jun. 9, 2022

(54) CONTACT TERMINAL, INSPECTION JIG, AND INSPECTION DEVICE

(71) Applicant: NIDEC READ CORPORATION, Ukyo-ku, Kyoto (JP)

(72) Inventors: Yusuke YOKOTA, Kyoto (JP); Norihiro OTA, Kyoto (JP)

(21) Appl. No.: 17/598,301

(22) PCT Filed: Mar. 12, 2020
(86) PCT No.: PCT/JP2020/010930

§ 371 Date: Sep. 27, 2021

(30) Foreign Application Priority Data
Mar. 29, 2019 (JP) 2019-069270

(51) Int. Cl. G01R 1/067; G01R 1/04

(52) U.S. Cl. CPC G01R 1/06722; G01R 1/0416; G01R 1/06738

(57) ABSTRACT

A contact terminal includes a tubular body extending in an axial direction of the contact terminal and having conductivity; a bar-shaped first conductor having conductivity and capable of coming into contact with an inspection target; and a bar-shaped second conductor having conductivity. The first conductor includes: a first protrusion that protrudes from the tubular body toward one side in the axial direction; and a first insertion portion provided at the other end of the first conductor in the axial direction and disposed in the tubular body. The second conductor includes a second insertion portion disposed in the tubular body. The tubular body includes: a spring portion configured in a spiral shape along a peripheral surface of the tubular body; and a first body portion connected to one side in the axial direction of the spring portion. The first insertion portion is fixed to the first body portion.

### CROSS-REFERENCE TO RELATED APPLICATIONS

This is a U.S. National Stage Application No., filed under 35 U.S.C. § 371, of International Application No. PCT/JP2020/010930, filed on Mar. 12, 2020, and claims priority under 35 U.S.C. § 119(a) and 35 U.S.C. § 365(b) from Japanese Patent Application No. 2019-069270, filed on Mar. 29, 2019; the disclosures of which are incorporated herein by reference.

### FIELD

Various embodiments relate to a contact terminal used for inspection of an inspection target.

### BACKGROUND

Conventionally, a contact terminal to be brought into contact with an inspection target is known.

The contact terminal, which is conventionally known, includes a tubular body, a first central conductor, and a second central conductor. The tubular body is formed in a cylindrical shape by a material having conductivity. The tubular body is formed with a first spring portion and a second spring portion that extend and contract in the axial direction of the tubular body. A joining portion that connects the first spring portion and the second spring portion is provided at a central portion of the tubular body in the axial direction.

The first central conductor and the second central conductor are made of a conductive material and formed in a rod shape. A first swell portion is provided at the tip of the first central conductor. The first swell portion is disposed in the joining portion in a state where the first central conductor is fixed to one end portion of the tubular body. A second swell portion is provided at the tip of the second central conductor. The second swell portion is disposed in the joining portion in a state where the second central conductor is fixed to the other end portion of the tubular body.

When a base plate is attached to a support member that supports the contact terminal having the above configuration, one end portion of the first central conductor is brought into pressure contact with the electrode of the base plate according to a biasing force of the first spring portion and the second spring portion, and the one end portion of the first central conductor and the electrode are held in a conductive contact state.

When the inspection target is inspected using the contact terminal, the other end portion of the second central conductor is brought into pressure contact with the inspection target point of the inspection target according to the biasing force of the first spring portion and the second spring portion, and the other end portion of the second central conductor and the inspection target point are held in the conductive contact state.

As a result, a contact point is formed by contact between the inspection target and the other end portion of the second central conductor, contact between the second swell portion and the joining portion, contact between the joining portion and the first swell portion, and contact between the one end portion of the first central conductor and the electrode, and a current path is formed.

However, in the conventional contact terminal, two contact points are formed as contact points inside the contact terminal, that is, a sliding contact point between the second swell portion and the joining portion and a sliding contact point between the joining portion and the first swell portion, and thus there is room for improving contact resistance inside the contact terminal.

### SUMMARY

An exemplary contact terminal of the present disclosure includes: a tubular body extending in an axial direction of the contact terminal and having conductivity; a bar-shaped first conductor having conductivity and capable of coming into contact with an inspection target; and a bar-shaped second conductor having conductivity. The first conductor includes: a first protrusion that protrudes from the tubular body toward one side in the axial direction; and a first insertion portion provided at the other end of the first conductor in the axial direction and disposed in the tubular body. The second conductor includes a second insertion portion disposed in the tubular body. The tubular body includes: a spring portion configured in a spiral shape along a peripheral surface of the tubular body; and a first body portion connected to one side in the axial direction of the spring portion. The first insertion portion is fixed to the first body portion, and an end side notch extending along the axial direction from an end surface on one side in the axial direction of the tubular body is provided on a peripheral surface of the first body portion.

The above and other elements, features, steps, characteristics and advantages of the present disclosure will become more apparent from the following detailed description of the various embodiments with reference to the attached drawings.

### BRIEF DESCRIPTION OF THE DRAWINGS

In the drawings, like reference characters generally refer to the same parts throughout the different views. In the drawings, components given the same reference numerals denote the same components, and description thereof will be omitted. The drawings are not necessarily to scale, emphasis instead generally being placed upon illustrating the principles of the disclosed embodiments. In the following description, various embodiments described with reference to the following drawings, in which:

FIG. 1 is a schematic diagram illustrating an overall configuration of an inspection device according to an exemplary embodiment of the present disclosure;

FIG. 2 is a side view illustrating a contact terminal according to a first embodiment;

FIG. 3 is a side sectional view of the contact terminal in the state of FIG. 2;

FIG. 4 is a side sectional view illustrating a state in which a load is applied to the contact terminal in the state of FIG. 3;

FIG. 5 is a perspective view of a main part illustrating assembly of a first conductor to a tubular body;

FIG. 6 is a perspective view of a main part illustrating a snap-fit structure for fixing the first conductor to the tubular body;

FIG. 7 is a side view of a contact terminal according to a comparative example;

FIG. 8 is a side sectional view of the contact terminal in the state of FIG. 7;

FIG. 9 is a side sectional view illustrating a state in which a load is applied to the contact terminal in the state of FIG. 8;

FIG. 10 is a diagram illustrating a state in which the contact terminal according to the first embodiment is supported by a support member;

FIG. 11 is a diagram illustrating a state in which a contact terminal according to a comparative example is supported by the support member;

FIG. 12 is a side view illustrating a contact terminal according to a modification of the first embodiment;

FIG. 13 is a side view illustrating a contact terminal according to a second embodiment;

FIG. 14 is a side view illustrating the contact terminal in a state in which the first conductor and the second conductor are exchanged from the state of FIG. 13 and fixed to the tubular body; and

FIG. 15 is a side view illustrating a contact terminal according to a modification of the second embodiment.

### DETAILED DESCRIPTION

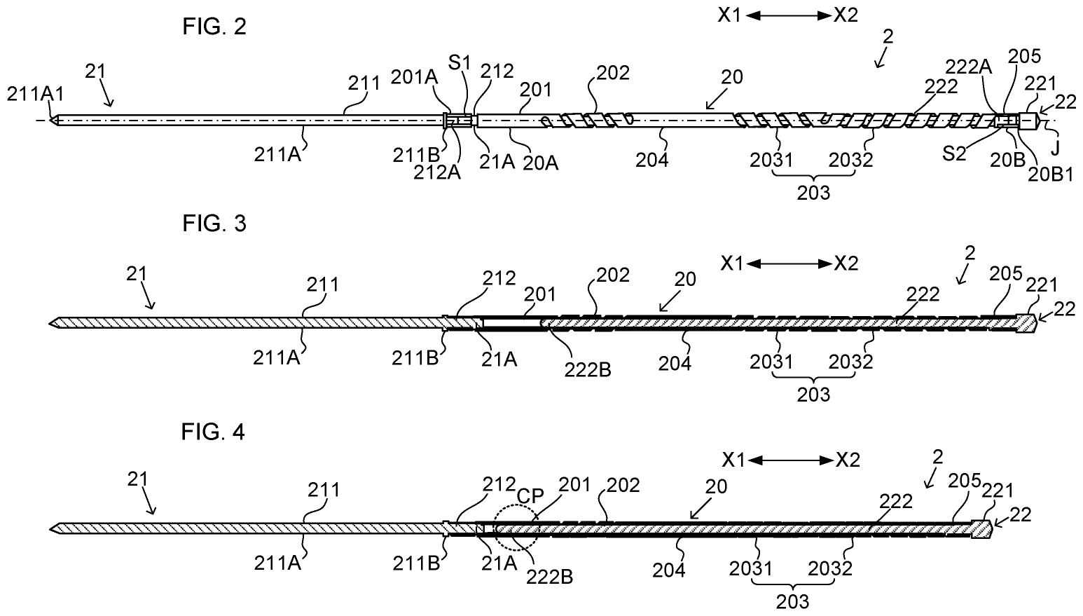

Hereinafter, exemplary embodiments of the present disclosure will be described with reference to the drawings. In the following, a direction parallel to a central axis J (see FIGS. 2, 7, and 13) of a contact terminal is defined as an “axial direction”. In the drawings, “X1” represents a first side in the axial direction and “X2” represents a second side in the axial direction. In addition, a direction about the central axis J will be referred to as a “circumferential direction”.

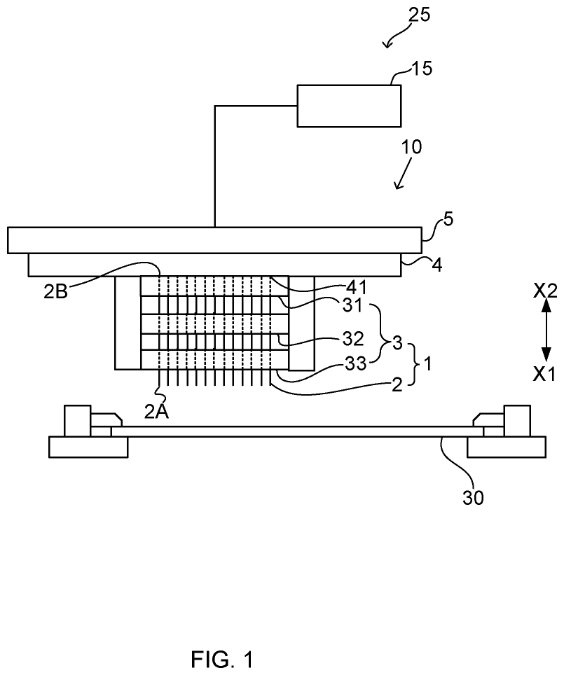

An overall configuration of an inspection device 25 according to an exemplary embodiment of the present disclosure will be described with reference to FIG. 1. It should be noted in FIG. 1 that one axial direction X1 side corresponds to a lower side and the other axial direction X2 side corresponds to an upper side.

The inspection device 25 illustrated in FIG. 1 electrically inspects an inspection target 30. The inspection device 25 includes an inspection jig 10 and an inspection processing unit 15. The inspection jig 10 is configured as, for example, a so-called probe card.

The inspection target 30 is, for example, a semiconductor wafer in which a plurality of circuits is formed on a semiconductor substrate such as silicon. The semiconductor wafer is diced to be divided into semiconductor chips having the individual circuits. In addition to the semiconductor wafer, the inspection target 30 can be, for example, a semiconductor chip, a chip size package (CSP), or an electronic component such as a semiconductor element.

In addition, the inspection target 30 may be a substrate. In this case, the inspection target 30 may be, for example, a board such as a printed circuit board, a glass epoxy board, a flexible board, a ceramic multilayer circuit board, a package board for a semiconductor package, an interposer board, or a film carrier. The inspection target 30 may alternatively be an electrode plate for a display such as a liquid crystal display, an electro-luminescence (EL) display, or a touch screen display or an electrode plate for a touch screen.

The inspection target 30 may alternatively be a product obtained by packaging technology called embedded multi-die interconnect bridge (EMIB). According to EMIB, a small silicon substrate called a silicon bridge is embedded in a package resin board, and fine wires are formed on a surface of the silicon bridge in high density, so that adjacent silicon dies are mounted on the package resin board in proximity to each other.

As illustrated in FIG. 1, the inspection jig 10 includes a probe head 1, a pitch conversion unit 4, and a connection plate 5. The probe head 1 includes a contact terminal (probe) 2 and a support member 3.

The support member 3 supports a plurality of contact terminals 2 formed in a rod shape. That is, the inspection jig 10 includes the plurality of contact terminals 2 and the support member 3 that supports the plurality of contact terminals 2.

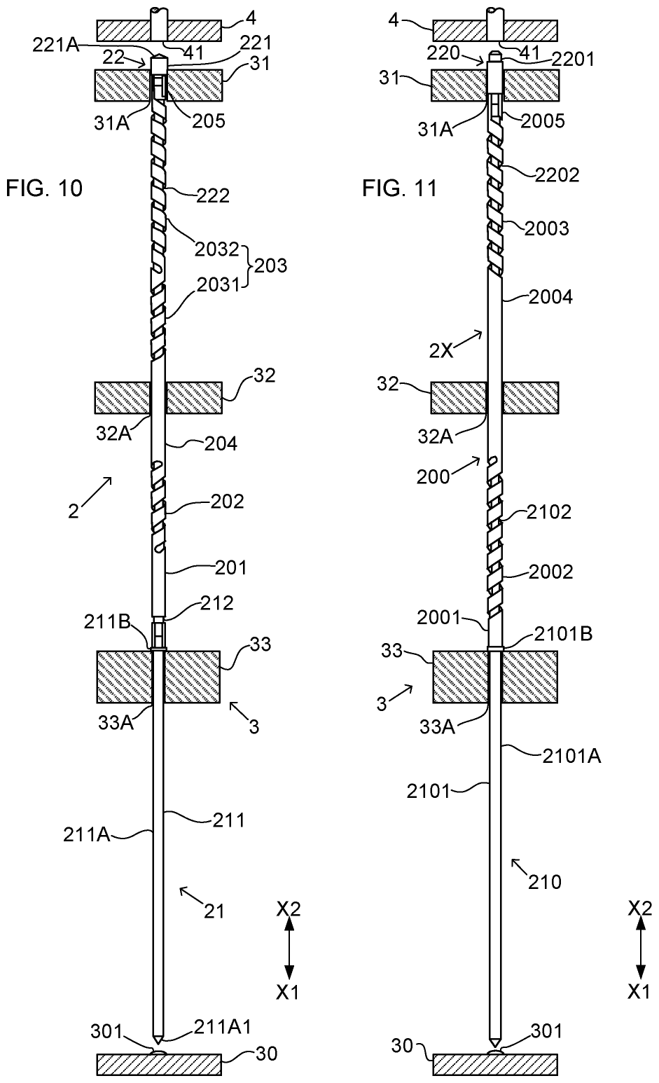

The pitch conversion unit 4 is disposed above the support member 3 and fixed to the support member 3. The contact terminal 2 has one end portion 2A on the one axial direction X1 side and the other end portion 2B on the other axial direction X2 side. The other end portion 2B is connected to each of first electrodes 41 (see FIG. 10) provided at the lower end portion of the pitch conversion unit 4.

Each of the first electrodes 41 is electrically connected to each of the second electrodes (not illustrated) formed at the upper end portion of the pitch conversion unit 4 via a wiring portion (not illustrated) formed inside the pitch conversion unit 4. The pitch conversion unit 4 converts a first pitch between the contact terminals 2 into a second pitch between the second electrodes. The second pitch is longer than the first pitch. The pitch conversion unit 4 is formed of, for example, a multilayer wiring substrate such as a multi-layer organic (MLO) or a multi-layer ceramic (MLC).

The connection plate 5 is configured such that the pitch conversion unit 4 is detachable. A plurality of electrodes (not illustrated) connected to the second electrode is formed on the connection plate 5. Each of the electrodes of the connection plate 5 is electrically connected to the inspection processing unit 15 by, for example, a cable, a connection terminal, or the like (not illustrated).

The inspection processing unit 15 includes, for example, a power supply circuit, a voltmeter, an ammeter, a microcomputer, and so on. The inspection processing unit 15 controls a drive mechanism (not illustrated) to move the inspection jig 10.

In a case where the inspection target 30 is, for example, a semiconductor wafer, inspection points such as pads or bumps are formed for each circuit corresponding to an individual semiconductor chip to be obtained by dicing the inspection target 30. The inspection processing unit 15 defines a certain region of the plurality of circuits on the inspection target 30 as an inspection region, and moves the inspection jig 10 to a position at which the contact terminals 2 located above are opposite the inspection points located below in the inspection region. At this time, the one end portions 2A of the contact terminals 2 of the inspection jig 10 are directed toward the inspection target 30.

Then, the inspection processing unit 15 moves the inspection jig 10 downward to bring the contact terminal 2 into contact with each inspection point in the inspection region. In this manner, the inspection points and the inspection processing unit 15 are electrically connected.

The inspection processing unit 15 supplies a current or a voltage for inspection to each inspection point of the inspection target 30 via each contact terminal 2 in the above-described state, and executes inspection of the inspection target 30 such as disconnection or short circuit of a circuit pattern based on a voltage signal or a current signal obtained from each contact terminal 2. Alternatively, the inspection processing unit 15 may measure an impedance of the inspection target 30 based on the voltage signal or the current signal obtained from each contact terminal 2 by supplying AC current or voltage to the inspection points.

That is, the inspection device 25 includes the inspection jig 10 and the inspection processing unit 15 that performs inspection of the inspection target 30 based on the electrical signal obtained by bringing the contact terminal 2 into contact with the inspection point provided in the inspection target 30.

When the inspection in the inspection region of the inspection target 30 is completed, the inspection processing unit 15 moves the inspection jig 10 upward, translates the inspection jig 10 to a position corresponding to the new inspection region, moves the inspection jig 10 downward, and brings the contact terminal 2 into contact with each inspection point in the new inspection region to perform the inspection. In this manner, the entire inspection target 30 is inspected by performing the inspection while sequentially changing the inspection region.

The position of the inspection jig 10 may be fixed, and the inspection target 30 may be moved with respect to the inspection jig 10.

Hereinafter, the configuration of the contact terminal 2 will be described in more detail. FIG. 2 illustrates a case where no load is applied to the contact terminal 2 and a first spring portion 202 and a second spring portion 203 are in a natural length state.

As illustrated in FIG. 2, the contact terminal 2 includes a conductive tubular body 20 extending in the axial direction of the contact terminal 2, a conductive bar-shaped first conductor (plunger) 21, and a conductive bar-shaped second conductor (plunger) 22. The first conductor 21 and the second conductor 22 are formed of, for example, a conductive material such as a nickel alloy.

The tubular body 20 has a cylindrical shape, and is formed of, for example, a nickel or nickel-alloy tube having an outer diameter of about 25 to 300 μm and an inner diameter of about 10 to 250 μm. Preferably, the tubular body 20 has, on its inner peripheral surface, a plating layer such as a gold plating layer. In addition, the tubular body 20 may have an outer peripheral surface coated with an insulation coating as necessary.

The tubular body 20 includes a first body portion 201, a first spring portion 202, a second spring portion 203, and a second body portion 204. The first body portion 201 is provided at one axial end portion 20A of the tubular body 20. The first spring portion 202 is disposed to be connected to the other axial direction X2 side of the first body portion 201. The second spring portion 203 is disposed on the other axial direction X2 side with respect to the first spring portion 202. The second body portion 204 is disposed between the first spring portion 202 and the second spring portion 203.

The first spring portion 202 and the second spring portion 203 are formed as a spiral body extending in a spiral shape along the peripheral surface of the tubular body 20. The first body portion 201 and the second body portion 204 have a cylindrical shape that is not formed in a spiral shape.

That is, the tubular body 20 includes the spring portions 202 and 203 formed in a spiral shape along the peripheral surface of the tubular body 20 and the first body portion 201 connected to one axial direction X1 side of the spring portion 202 and not formed in a spiral shape.

In order to produce a tubular body having such a spiral body, for example, a gold plating layer is formed by plating on the outer periphery of a core material, and then a nickel electroforming layer is formed by electroforming on the outer periphery of the formed gold plating layer. A resist layer is formed on an outer periphery of the nickel electroforming layer, and then is exposed with a laser, so that the resist layer is partially removed in a spiral shape. Etching is performed using the resist layer as a masking material to remove the nickel electroforming layer at a place where the resist layer has been spirally removed. Then, after the resist layer is removed, the gold plating layer at the place where the nickel electroforming layer is spirally removed is removed, and the core material is removed while the gold plating layer is left on the inner periphery of the nickel electroforming layer to form a tubular body.

The shape of the tubular body 20 is not limited to the cylindrical shape, and may be, for example, a cylindrical shape having a rectangular annular shape such as a quadrangle or a hexagon in an axial sectional view.

The first conductor 21 includes a first protrusion 211 and a first insertion portion 212. The first conductor 21 and the second conductor 22 to be described later are formed by, for example, cutting using a lathe.

The first protrusion 211 includes a bar-shaped main body 211A and a flange 211B connected to the other axial direction X2 side of the bar-shaped main body 211A. The bar-shaped main body 211A has a tip portion 211A1 on the one axial direction X1 side. The tip portion 211A1 is in contact with an inspection point of the inspection target 30 as described later. That is, the first conductor 21 can come into contact with the inspection target 30.

In the example of FIG. 2, the tip portion 211A1 has a conical shape, but is not limited thereto, and may have, for example, a truncated cone shape, a hemispherical shape, a planar shape, or the like.

The first insertion portion 212 is connected to the other axial direction X2 side of the flange 211B and is provided at another axial end portion 21A of the first conductor 21.

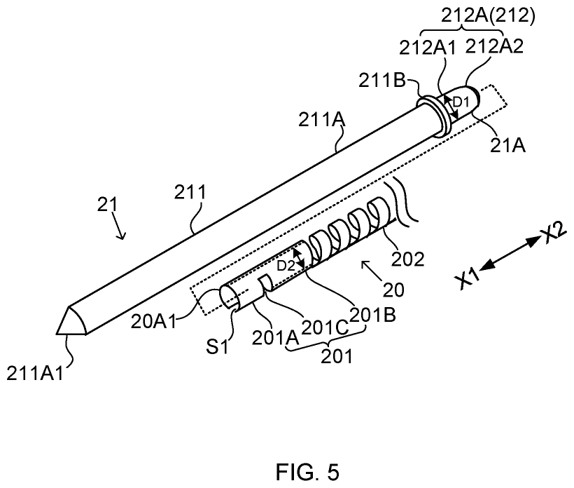

Here, assembling of the first conductor 21 to the tubular body 20 will be described with reference to FIG. 5. The first insertion portion 212 has a press-fitting portion 212A. Here, the first body portion 201 has a fixing portion 201A on the one axial direction X1 side. The peripheral surface of the fixing portion 201A is provided with an end side notch S1 formed by being cut along the axial direction from one axial end surface 20A1 of the tubular body 20. That is, the peripheral surface of the first body portion 201 is provided with the end side notch S1 extending along the axial direction from the one axial end surface 20A1 of the tubular body 20.

The outer diameter D1 of one axial end portion 212A1 of the press-fitting portion 212A is larger than the inner diameter of the fixing portion 201A in a state before the first conductor 21 is fixed to the tubular body 20. The other axial end portion 212A2 of the press-fitting portion 212A is connected to the other axial direction X2 side of the one axial end portion 212A. The outer diameter of the other axial end portion 212A2 gradually decreases from the outer diameter of the one axial end portion 212A1 toward the other axial direction X2 side. When the first conductor 21 is assembled to the tubular body 20, the other axial end portion 212A2 is inserted into the fixing portion 201A from the one axial direction X1 side. At this time, when the one axial end portion 212A1 is inserted into the fixing portion 201A, the end side notch S1 expands, and the press-fitting portion 212A is press-fitted into the fixing portion 201A. In this state, the outer diameter D1 of the one axial end portion 212A1 is equal to the inner diameter of the fixing portion 201A, and is larger than the inner diameter D2 of the other axial end portion 201B of the first body portion 201. Since the outer diameter of the flange 211B is larger than the inner diameter of the fixing portion 201A, the flange 211B comes into contact with the fixing portion 201A and the pushing of the first conductor 21 is restricted. As a result, the first bar-shaped main body 211A and the flange 211B are disposed in the tubular body 20 on the one axial direction X1 side.

That is, the first conductor 21 includes the first protrusion 211 that protrudes to the one axial direction X1 side from the tubular body 20, and the first insertion portion 212 that is provided at the other axial end portion 21A of the first conductor 21 and disposed inside the tubular body 20. The first insertion portion 212 is fixed to the first body portion 201.

Further, the fixing of the first conductor 21 and the second conductor 22 described later to the tubular body 20 is not limited to press-fitting, and may be performed by, for example, welding or caulking. However, since the end side notch S1 is provided as illustrated in FIG. 5, the press-fitted portion easily expands. Therefore, the distance of the press-fitted portion can be shortened, and the axial length of the contact terminal 2 can be shortened.

As illustrated in FIG. 5, the first body portion 201 has a circumferential notch 201C. The circumferential notch 201C is connected to the other axial direction X2 side of the end side notch S1, and is formed in a shape cut along the circumferential direction away from the end side notch S1 from both circumferential ends of the end side notch S1. By providing the circumferential notch 201C, even if the portion press-fitted is expanded, the portion of the first body portion 201 on the other axial direction X2 side is less likely to expand than the circumferential notch 201C. Therefore, when the second conductor 22 comes into contact with the portion as described later, the contact tends to be stable.

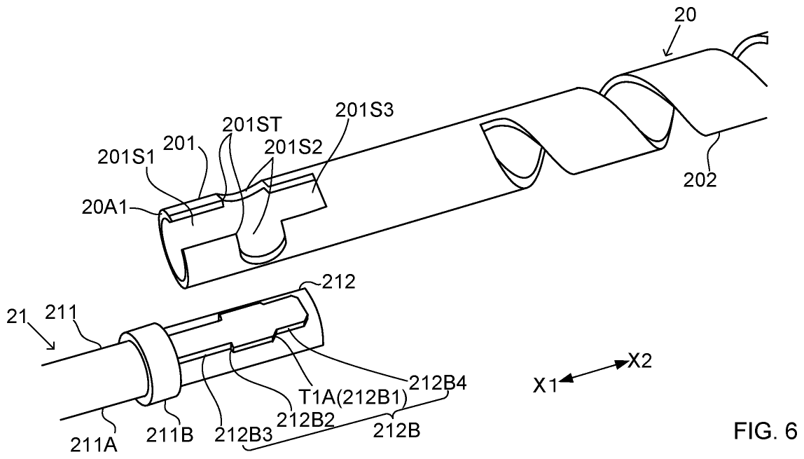

The first conductor 21 and the second conductor 22 to be described later may be fixed to the tubular body 20 by snap-fitting. When the first conductor 21 is fixed to the tubular body 20 by snap-fitting, as illustrated in FIG. 6, the first body portion 201 has an end side notch 201S1, a circumferential notch 201S2, and a center side notch 201S3.

The end side notch 201S1 is formed by being cut toward the other axial direction X2 side from the one axial end surface 20A1 of the tubular body 20 on the peripheral surface on the one axial direction X1 side of the first body portion 201. The circumferential notch 201S2 is connected to the other axial direction X2 side of the end side notch 201S1, and is formed in a shape cut along the circumferential direction away from the end side notch 201S1 from both circumferential end portions 201ST of the end side notch 201S1. The center side notch 201S3 is connected to the other axial direction X2 side of the circumferential notch 201S2, and is formed by cutting the peripheral surface of the first body portion 201 in the axial direction.

As illustrated in FIG. 6, the first insertion portion 212 includes a snap-fit portion 212B. The snap-fit portion 212B includes an inclined portion 212B1, a wall surface portion 212B2, an end side rib 212B3, and a center side rib 212B4. The inclined portion 212B1 has an inclined surface T1A. The inclined surface T1A is separated from the central axis J as it goes toward the one axial direction X1 side as viewed in the direction perpendicular to the axial direction. The wall surface portion 212B2 is disposed in the inclined portion 212B1 on the one axial direction X1 side.

The end side rib 212B3 is connected to the wall surface portion 212B2 on the one axial direction X1 side and is connected to the flange 211B on the other axial direction X2 side. The center side rib 212B4 is connected to the inclined portion 212B1 on the other axial direction X2 side.

When the first insertion portion 212 is fixed to the first body portion 201, the center side rib 212B4 is inserted into the end side notch 201S1. Then, when the inclined portion 212B1 is brought into contact with the end side notch 201S1 and the first insertion portion 212 is pushed toward the other axial direction X2 side, the end side notch 201S1 expands. When the first insertion portion 212 is pushed as it is, the wall surface portion 212B2 is accommodated in the circumferential notch 201S2, and the end side notch 201S1 returns to the original shape. Therefore, the wall surface portion 212B2 can come into contact with the tubular body 20. In this state, the end side rib 212B3 is located inside the end side notch 201S1, and the center side rib 212B4 is located inside the center side notch 201S3.

As a result, it is possible to suppress the first conductor 21 from coming off the tubular body 20 in the axial direction and to regulate the rotation of the first conductor 21 with respect to the tubular body 20 in the circumferential direction by a simple assembling process.

Returning to the description of FIG. 2, the second conductor 22 includes a second protrusion 221 and a second insertion portion 222. The second insertion portion 222 is connected to the second protrusion 221 on the one axial direction X1 side.

The second insertion portion 222 has a press-fitting portion 222A as the other axial end portion. Here, the tubular body 20 has a fixing portion 205 connected to the other axial direction X2 side of the second spring portion 203 at the other axial end portion 20B. The peripheral surface of the fixing portion 205 is provided with an end side notch S2 formed by being cut along the axial direction from the other axial end surface 20B1 of the tubular body 20.

The outer diameter of the press-fitting portion 222A is larger than the inner diameter of the fixing portion 205 in a state before the second conductor 22 is fixed to the tubular body 20. When the second conductor 22 is assembled to the tubular body 20, the second insertion portion 222 is inserted into the fixing portion 205 from the other axial direction X2 side. At this time, when the press-fitting portion 222A is inserted into the fixing portion 205, the end side notch S2 expands, and the press-fitting portion 222A is press-fitted into the fixing portion 205. Since the outer diameter of the second protrusion 221 is larger than the inner diameter of the fixing portion 205, the second protrusion 221 comes into contact with the fixing portion 205 and the pushing of the second conductor 22 is restricted. With such a configuration, the second protrusion 221 is disposed in the tubular body 20 on the other axial direction X2 side. That is, the second protrusion 221 protrudes from the tubular body 20 toward the other axial direction X2 side.

In this manner, the first conductor 21 and the second conductor 22 are fixed to the tubular body 20 to form the contact terminal 2.

As illustrated in FIG. 3, the second insertion portion 222 extends in the axial direction to the first body portion 201 through the fixing portion 205, the second spring portion 203, the second body portion 204, and the first spring portion 202 inside the tubular body 20. That is, the second conductor 22 has the second insertion portion 222 disposed inside the tubular body 20. As a result, one axial end portion 222B of the second insertion portion 222 is disposed inside the first body portion 201.

FIG. 4 illustrates a state in which the first spring portion 202 and the second spring portion 203 are compressed by applying a load to the contact terminal 2. In this case, the second conductor 22 moves to the one axial direction X1 side as compared with the state of FIG. 3. As a result, the one axial end portion 222B of the second insertion portion 222 moves to the one axial direction X1 side while being in contact with the first body portion 201. On the other hand, the first insertion portion 212 is fixed to the first body portion 201 by press fitting. Therefore, the sliding contact point of the contact terminal 2 is only the contact point CP due to the contact between the one axial end portion 222B and the first body portion 201. The current path in the contact terminal 2 is a path through the first insertion portion 212, the first body portion 201, the contact point CP, and the second insertion portion 222.

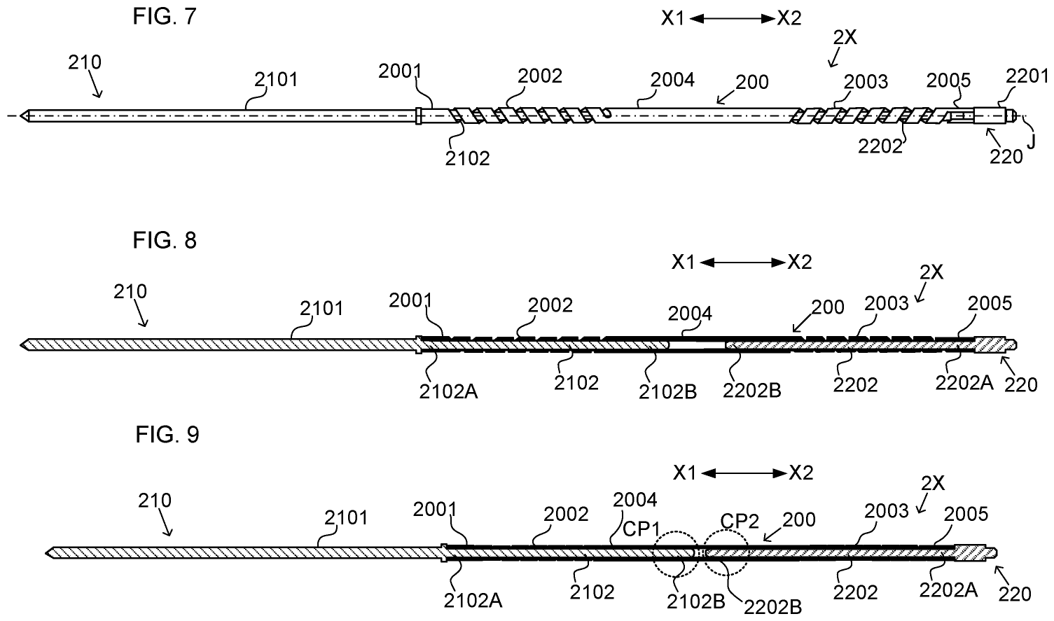

Here, a contact terminal 2X according to a comparative example will be described with reference to FIGS. 7 to 9. As illustrated in FIG. 7, the contact terminal 2X includes a tubular body 200, a first conductor 210, and a second conductor 220.

The tubular body 200 includes a first body portion 2001, a first spring portion 2002, a second spring portion 2003, a second body portion 2004, and a third body portion 2005. The first conductor 210 includes a first protrusion 2101 and a first insertion portion 2102. The second conductor 220 includes a second protrusion 2201 and a second insertion portion 2202. FIGS. 7 and 8 illustrate a case where no load is applied to the contact terminal 2X and the first spring portion 2002 and the second spring portion 2003 are in a natural length state.

One axial end portion 2102A of the first insertion portion 2102 is fixed to the first body portion 2001 by press fitting. Thus, the first conductor 210 is fixed to the tubular body 200. The other axial end portion 2202A of the second insertion portion 2202 is fixed to the third body portion 2005 by press fitting. As a result, the second conductor 220 is fixed to the tubular body 200.

As illustrated in FIG. 8, in a state where the first conductor 210 and the second conductor 220 are fixed to the tubular body 20, the other axial end portion 2102B of the first insertion portion 2102 and one axial end portion 2202B of the second insertion portion 2202 are disposed inside the second body portion 2004.

FIG. 9 illustrates a state in which the first spring portion 2002 and the second spring portion 2003 are compressed by applying a load to the contact terminal 2X. In this case, the first conductor 210 moves to the other axial direction X2 side as compared with the state in FIG. 8, and the second conductor 220 moves to the one axial direction X1 side as compared with the state in FIG. 8. Therefore, the sliding contact point in the contact terminal 2X becomes a first contact point CP1 by the contact between the other axial end portion 2102B and the second body portion 2004 and a second contact point CP2 by the contact between the one axial end portion 2202B and the second body portion 2004. The current path in the contact terminal 2X is a path through the first contact point CP1, the second body portion 2004, and the second contact point CP2.

As described above, in the contact terminal 2 according to the first embodiment, the number of sliding contact points can be reduced as compared with the contact terminal 2X according to the comparative example, and the contact resistance inside the contact terminal can be reduced. In addition, the contact resistance can be stabilized.

In addition, in the contact terminal 2X according to the comparative example, as illustrated in FIG. 8, the axial length of the first conductor 210 to be brought into contact with the inspection target 30 is longer than the axial length of the second conductor 220, and a difference between both lengths is large. On the other hand, in the contact terminal 2 according to the first embodiment, as illustrated in FIG. 3, the axial length of the first conductor 21 is shortened and the axial length of the second conductor 22 is lengthened, so that the difference between both lengths can be reduced. As a result, the first conductor 21 and the second conductor 22 can be easily manufactured.

In addition, by providing the end side notch S1 in the first body portion 201, a portion where the second conductor 22 slides can be secured on the other axial direction X2 side from the end side notch S1. The effect of providing an end side slit 201S1 illustrated in FIG. 6 is also the same.

As illustrated in FIG. 4, the one axial end portion 222B of a second insertion portion 22 contacts the first body portion 201. As a result, since a current path passing through a first insertion portion 21, the first body portion 201, and the second insertion portion 22 is formed, the electric resistance value of the current path can be further reduced.

FIG. 10 is a diagram illustrating a state in which the contact terminal 2 according to the first embodiment is supported by the support member 3. FIG. 11 illustrates a state in which the contact terminal 2X according to the comparative example is supported by the support member 3.

As illustrated in FIG. 10, the support member 3 includes an upper support body 31, an intermediate support body 32, and a lower support body 33. Here, a configuration in which the contact terminal 2 according to the first embodiment is supported by the support member 3 will be described.

The lower support body 33 has a support hole 33A which is a through hole penetrating in the axial direction. The sectional area of the support hole 33A as viewed in the axial direction is slightly larger than the sectional area of the bar-shaped main body 211A as viewed in the axial direction and is smaller than the sectional area of the flange 211B as viewed in the axial direction. As a result, the bar-shaped main body 211A can be inserted into the support hole 33A, and the flange 211B prevents the contact terminal 2 from falling off.

The intermediate support body 32 is disposed above the lower support body 33 and has a support hole 32A which is a through hole coaxial with the support hole 33A. The sectional area of the support hole 32A as viewed in the axial direction is slightly larger than the outer sectional area of the second body portion 204 as viewed in the axial direction. Thus, the second body portion 204 can be inserted into the support hole 32A.

The upper support body 31 is disposed above the intermediate support body 32 and has a support hole 31A which is a through hole coaxial with the support hole 32A. The sectional area of the support hole 31A as viewed in the axial direction is slightly larger than the outer sectional areas of the fixing portion 205 and the second protrusion 221 as viewed in the axial direction. Accordingly, the fixing portion 205 and the second protrusion 221 can be inserted into the support hole 31A.

When the contact terminal 2 is supported by the support member 3, the bar-shaped main body 211A is sequentially inserted into the support hole 31A, the support hole 32A, and the support hole 33A from above. The support holes 31A and 32A have a cross section as viewed in the axial direction through which the flange 211B can be inserted.

In addition, the present disclosure is not limited to the above, and the support member 3 may be an embodiment that can be disassembled to each of the upper support body 31, the intermediate support body 32, and the lower support body 33. In this case, the bar-shaped main body 211A is inserted into the lower support body 33. Next, the intermediate support body 32 is fixed to the lower support body 33 while the second body portion 204 is inserted into the intermediate support body 32. Then, the upper support body 31 is fixed to the intermediate support body 32 while the fixing portion 205 and the second protrusion 221 are inserted into the upper support body 31.

In a state where the probe head 1 is assembled by the contact terminal 2 and the support member 3, the bar-shaped main body 211A is inserted into the support hole 33A. The flange 211B is brought into contact with the upper surface of the lower support body 33. The second body portion 204 is inserted into the support hole 32A. The fixing portion 205 and the second protrusion 221 are inserted into the support hole 31A. Thus, the contact terminal 2 is supported by the support member 3.

Then, the upper surface of the upper support body 31 is pressed against the lower surface of the pitch conversion unit 4 while bringing a tip portion 221A of the second protrusion 221 into contact with the first electrode 41 exposed on the lower surface of the pitch conversion unit 4. Thus, the support member 3 is fixed to the pitch conversion unit 4. At this time, the first spring portion 202 and the second spring portion 203 are compressed in the axial direction. As a result, a tip portion 221A1 is pressed against the first electrode 41 by the elastic force of the spring portions 202 and 203, and the tip portion 221A and the first electrode 41 are held in a stable conductive contact state.

Further, when the inspection target 30 is inspected, the tip portion 211A1 of the bar-shaped main body 211A is brought into contact with an inspection point 301 of the inspection target 30. At this time, a force toward the other axial direction X2 side is applied to the tip portion 211A1, and the first spring portion 202 and the second spring portion 203 are compressed in the axial direction. As a result, the tip portion 211A1 is pressed against the inspection point 301 by the elastic force of the spring portions 202 and 203, and the tip portion 211A1 and the inspection point 301 are held in a stable conductive contact state.

In the contact terminal 2, the spring includes the first spring portion 202 and the second spring portion 203 disposed on the other axial direction X2 side with respect to the first spring portion 202, and the tubular body 20 includes the second body portion 204 disposed between the first spring portion 202 and the second spring portion 203 and not formed in a spiral shape. As a result, the second body portion 204 located in the middle of the tubular body 20 can be supported by the intermediate support body 32, and buckling of the tubular body 20 can be suppressed.

The second spring portion 203 includes a third spring portion 2031 having the same winding direction as that of the first spring portion 202, and a fourth spring portion 2032 connected to the third spring portion 2031 and having a winding direction opposite to that of the first spring portion 202. When the first conductor 21 is pressed against the inspection target 30, the first spring portion 202 is compressed, and the first conductor 21 rotates in a predetermined direction with respect to the second body portion 204. Similarly, the second spring portion 203 is also compressed, and the second conductor 22 rotates with respect to the second body portion 204. Since the third spring portion 2031 included in the second spring portion 203 has the same winding direction as the first spring portion 202, the second conductor 22 is rotated in the same direction as the first conductor 21. On the other hand, since the winding direction of the fourth spring portion 2032 included in the second spring portion 203 is opposite to that of the first spring portion 202, the second conductor 22 is rotated in the opposite direction to that of the first conductor 21. Therefore, rotation of both ends of the contact terminal 2 due to compression of the contact terminal 2 can be suppressed.

As illustrated in FIG. 10, when the sum of the number of turns of the first spring portion 202 and the number of turns of the third spring portion 2031 is equal to the number of turns of the fourth spring portion 2032, the rotation of both ends of the contact terminal 2 can be further suppressed.

In comparison with the contact terminal 2X according to the comparative example illustrated in FIG. 11, in the contact terminal 2 according to the first embodiment, it is preferable that the axial length of the first body portion 201 is made longer than the axial length of the first body portion 2001 of the contact terminal 2X in order to secure the amount of movement of the one axial end portion 222B (see FIG. 4) of the second insertion portion 222 inside the first body portion 201. Therefore, the number of turns of the first spring portion 202 is reduced as compared with the number of turns of the first spring portion 2002 of the contact terminal 2X, and the third spring portion 2031 is connected to the fourth spring portion 2032 in order to secure the number of turns. As a result, the second body portion 204 can be supported by the intermediate support body 32 without changing the position of the intermediate support body 32 from the case of the contact terminal 2X. That is, the support member 3 can be applied.

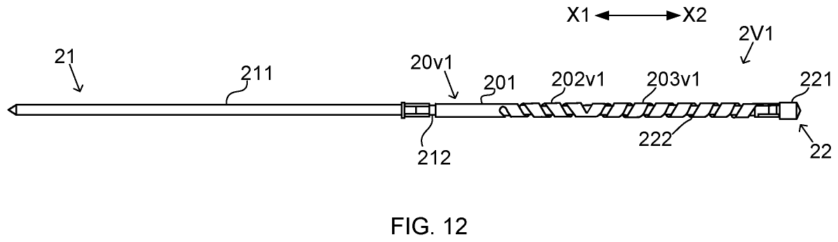

As illustrated in FIG. 12, in a contact terminal 2V1 according to a modification of the first embodiment, a tubular body 20v1 includes a first body portion 201, a first spring portion 202v1, and a second spring portion 203v1.

The first spring portion 202v1 corresponds to the first spring portion 202 in the contact terminal 2 (see FIG. 2) described above. The second spring portion 203v1 corresponds to the fourth spring portion 2032 of the contact terminal 2. The second spring portion 203v1 is connected to the other axial direction X2 side of the first spring portion 202v1. That is, the contact terminal 2V1 has a configuration in which the second body portion 204 and the third spring portion 2031 are omitted in the contact terminal 2.

That is, in the contact terminal 2V1, the spring includes the first spring portion 202v1 and the second spring portion 203v1 connected to the first spring portion 202v1 on the other axial direction X2 side, and the winding direction of the second spring portion 203v1 is opposite to the winding direction of the first spring portion 202v1. As a result, the axial length of the tubular body 20v1 can be shortened, and a member that supports the middle of the tubular body 20v1 can be made unnecessary.

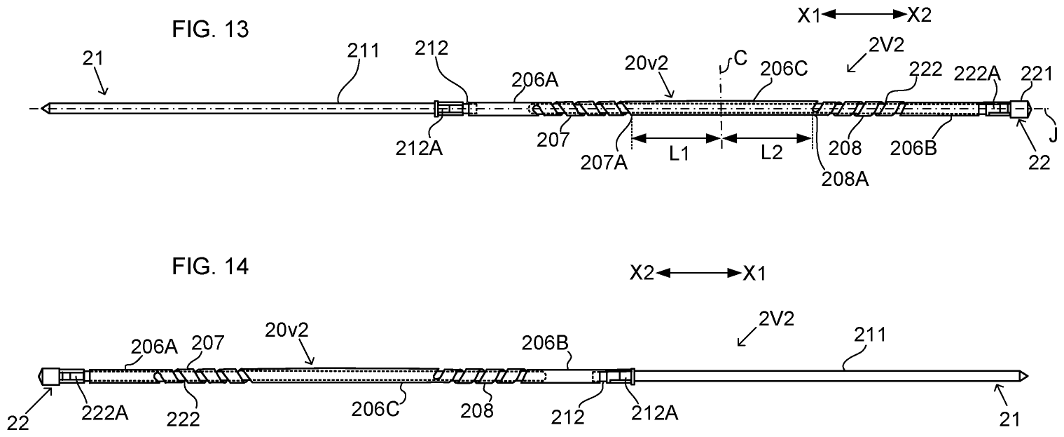

As illustrated in FIG. 13, a contact terminal 2V2 according to a second embodiment has a tubular body 20v2. The tubular body 20v2 includes a first body portion 206A, a fifth spring portion 207, a fourth body portion 206C, a sixth spring portion 208, and a third body portion 206B.

The other axial end portion 207A of the fifth spring portion 207 is disposed at a position away from an axial center C of the tubular body 20v2 by a first predetermined distance L1 toward the one axial direction X1 side. One axial end portion 208A of the sixth spring portion 208 is disposed at a position away from the axial center C of the tubular body 20v2 by a second predetermined distance L2 toward the other axial direction X2 side. The first predetermined distance L1 and the second predetermined distance L2 are equal. That is, in the contact terminal 2V2, the spring includes the fifth spring portion 207 and the sixth spring portion 208 arranged at symmetrical positions with respect to the axial center C of the tubular body 20v2.

The sixth spring portion 208 is disposed on the other axial direction X2 side of the fifth spring portion 207. The winding direction of the sixth spring portion 208 is opposite to that of the fifth spring portion 207, and the number of turns of the sixth spring portion 208 is the same as that of the fifth spring portion 207.

The first body portion 206A is connected to the fifth spring portion 207 on the one axial direction X1 side. The tubular body 2V2 has the third body portion 206B that is connected to the sixth spring portion 208 on the other axial direction X2 side and is not formed in a spiral shape. The axial length of the first body portion 206A is equal to the axial length of the third body portion 206B.

The fourth body portion 206C is disposed to be sandwiched between the fifth spring portion 207 and the sixth spring portion 208.

As illustrated in FIG. 13, the press-fitting portion 212A of the first insertion portion 212 is fixed to the first body portion 206A, whereby the first conductor 21 is fixed to the tubular body 20v2. Further, the press-fitting portion 222A of the second insertion portion 222 is fixed to the third body portion 206B, whereby the second conductor 22 is fixed to the tubular body 20v2. The second insertion portion 222 extends to the first body portion 206A via the third body portion 206B, the sixth spring portion 208, the fourth body portion 206C, and the fifth spring portion 207 inside the tubular body 20v2. As a result, a sliding contact point is formed by contact between the second insertion portion 222 and the first body portion 206A, and the effect similar to that of the first embodiment described above can be obtained.

Here, FIG. 14 is a side view illustrating the contact terminal 2V2 in a state where the first conductor 21 and the second conductor 22 are fixed to the tubular body 20v2 by being interchanged with FIG. 13. That is, in FIG. 14, the press-fitting portion 222A of the second insertion portion 222 is fixed to the first body portion 206A, and the press-fitting portion 212A of the first insertion portion 212 is fixed to the third body portion 206B. As a result, the second insertion portion 222 extends to the third body portion 206B via the first body portion 206A, the fifth spring portion 207, the fourth body portion 206C, and the sixth spring portion 208 inside the tubular body 20v2. As a result, a sliding contact point is formed by contact between the second insertion portion 222 and the third body portion 206B.

As described above, in the present embodiment, with the configuration of the tubular body 20v2, as illustrated in FIGS. 13 and 14, even when the first conductor 21 and the second conductor 22 are inserted and assembled to the tubular body 20v2 from any side in the axial direction, substantially the same contact terminal 2V2 can be assembled. Accordingly, workability of assembly can be improved.

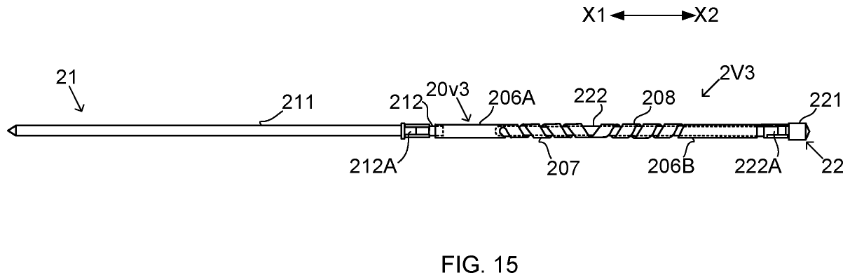

A contact terminal 2V3 according to a modification of the second embodiment shown in FIG. 15 has the following configuration as a difference from the second embodiment (see FIG. 13). In the tubular body 20v3 of the contact terminal 2V3, the sixth spring portion 208 is connected to the fifth spring portion 207 on the other axial direction X2 side. That is, the fourth body portion 206C of the second embodiment is omitted.

Even with such a contact terminal 2V3, even if the first conductor 21 and the second conductor 22 are inserted and assembled from any side in the axial direction with respect to the tubular body 20v3, substantially the same contact terminal 2V3 can be assembled.

While the embodiments of the present disclosure have been described above, the embodiments can be modified in various ways within the scope of the present disclosure.

Various embodiments of the present disclosure can be used for electrical inspection of various inspection targets.

Features of the above-described various embodiments and the modifications thereof may be combined appropriately as long as no conflict arises.

While various embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A contact terminal comprising:
a tubular body extending in an axial direction of the contact terminal and having conductivity;
a bar-shaped first conductor having conductivity and capable of coming into contact with an inspection target; and
a bar-shaped second conductor having conductivity,
wherein
the first conductor includes:
a first protrusion that protrudes from the tubular body toward one side in the axial direction; and
a first insertion portion provided at the other end of the first conductor in the axial direction and disposed in the tubular body,
the second conductor includes a second insertion portion disposed in the tubular body,
the tubular body includes:
a spring portion configured in a spiral shape along a peripheral surface of the tubular body; and
a first body portion connected to one side in the axial direction of the spring portion,
the first insertion portion is fixed to the first body portion, and
an end side notch extending along the axial direction from an end surface on one side in the axial direction of the tubular body is provided on a peripheral surface of the first body portion.

2. The contact terminal according to claim 1, wherein one end portion in the axial direction of the second insertion portion is in contact with the first body portion.

3. The contact terminal according to claim 1, wherein
the spring portion includes a first spring portion and a second spring portion disposed on the other side in the axial direction with respect to the first spring portion, and
the tubular body includes a second body portion disposed between the first spring portion and the second spring portion.

4. The contact terminal according to claim 3, wherein the second spring portion includes a third spring portion having the same winding direction as that of the first spring portion, and a fourth spring portion connected to the third spring portion and having a winding direction opposite to that of the first spring portion.

5. The contact terminal according to claim 4, wherein a sum of the number of turns of the first spring portion and the number of turns of the third spring portion is equal to the number of turns of the fourth spring portion.

6. The contact terminal according to claim 1, wherein
the spring portion includes a first spring portion and a second spring portion connected to the other side of the first spring portion in the axial direction, and
a winding direction of the second spring portion is opposite to a winding direction of the first spring portion.

7. The contact terminal according to claim 1, wherein
the spring portion includes a fifth spring portion and a sixth spring portion arranged at symmetrical positions with respect to a center of the tubular body in the axial direction,
the sixth spring portion is disposed on the other side of the fifth spring portion in the axial direction,
the sixth spring portion has a winding direction opposite to a winding direction of the fifth spring portion and has the same number of turns as the number of turns of the fifth spring portion,
the first body portion is connected to one side of the fifth spring portion in the axial direction,
the tubular body includes a third body portion connected to the other side of the sixth spring portion in the axial direction, and
an axial length of the first body portion is equal to an axial length of the third body portion.

8. The contact terminal according to claim 1, wherein
the first insertion portion includes a press-fitting portion, and
an outer diameter of one end portion of the press-fitting portion in the axial direction is larger than an inner diameter of the other end portion of the first body portion in the axial direction.

9. An inspection jig comprising:
a plurality of the contact terminals, each of the plurality of contact terminals comprising:
a tubular body extending in an axial direction of the contact terminal and having conductivity;
a bar-shaped first conductor having conductivity and capable of coming into contact with an inspection target; and
a bar-shaped second conductor having conductivity,
wherein
the first conductor includes:
a first protrusion that protrudes from the tubular body toward one side in the axial direction; and
a first insertion portion provided at the other end of the first conductor in the axial direction and disposed in the tubular body,
the second conductor includes a second insertion portion disposed in the tubular body,
the tubular body includes:
a spring portion configured in a spiral shape along a peripheral surface of the tubular body; and
a first body portion connected to one side in the axial direction of the spring portion,
the first insertion portion is fixed to the first body portion, and
an end side notch extending along the axial direction from an end surface on one side in the axial direction of the tubular body is provided on a peripheral surface of the first body portion; and
a support member that supports the plurality of the contact terminals.

10. An inspection device comprising:
the inspection jig according to claim 9; and
an inspection processing unit that performs inspection of an inspection target on a basis of an electrical signal obtained by bringing the contact terminal into contact with an inspection point provided on the inspection target.

11. The contact terminal according to claim 2, wherein
the spring portion includes a first spring portion and a second spring portion disposed on the other side in the axial direction with respect to the first spring portion, and
the tubular body includes a second body portion disposed between the first spring portion and the second spring portion.

12. The contact terminal according to claim 2, wherein
the spring portion includes a first spring portion and a second spring portion connected to the other side of the first spring portion in the axial direction, and
a winding direction of the second spring portion is opposite to a winding direction of the first spring portion.

13. The contact terminal according to claim 2, wherein
the spring portion includes a fifth spring portion and a sixth spring portion arranged at symmetrical positions with respect to a center of the tubular body in the axial direction,
the sixth spring portion is disposed on the other side of the fifth spring portion in the axial direction,
the sixth spring portion has a winding direction opposite to a winding direction of the fifth spring portion and has the same number of turns as the number of turns of the fifth spring portion,
the first body portion is connected to one side of the fifth spring portion in the axial direction,
the tubular body includes a third body portion connected to the other side of the sixth spring portion in the axial direction, and
an axial length of the first body portion is equal to an axial length of the third body portion.

14. The contact terminal according to claim 2, wherein
the first insertion portion includes a press-fitting portion, and
an outer diameter of one end portion of the press-fitting portion in the axial direction is larger than an inner diameter of the other end portion of the first body portion in the axial direction.

15. The contact terminal according to claim 3, wherein
the first insertion portion includes a press-fitting portion, and
an outer diameter of one end portion of the press-fitting portion in the axial direction is larger than an inner diameter of the other end portion of the first body portion in the axial direction.

16. The contact terminal according to claim 4, wherein
the first insertion portion includes a press-fitting portion, and
an outer diameter of one end portion of the press-fitting portion in the axial direction is larger than an inner diameter of the other end portion of the first body portion in the axial direction.

17. The contact terminal according to claim 5, wherein
the first insertion portion includes a press-fitting portion, and
an outer diameter of one end portion of the press-fitting portion in the axial direction is larger than an inner diameter of the other end portion of the first body portion in the axial direction.

18. The contact terminal according to claim 6, wherein
the first insertion portion includes a press-fitting portion, and
an outer diameter of one end portion of the press-fitting portion in the axial direction is larger than an inner diameter of the other end portion of the first body portion in the axial direction.

19. The contact terminal according to claim 7, wherein
the first insertion portion includes a press-fitting portion, and
an outer diameter of one end portion of the press-fitting portion in the axial direction is larger than an inner diameter of the other end portion of the first body portion in the axial direction.

20. An inspection jig comprising:
a plurality of the contact terminals, wherein each of the contact terminals comprises:
a tubular body extending in an axial direction of the contact terminal and having conductivity;
a bar-shaped first conductor having conductivity and capable of coming into contact with an inspection target; and
a bar-shaped second conductor having conductivity,
wherein
the first conductor includes:
a first protrusion that protrudes from the tubular body toward one side in the axial direction; and
a first insertion portion provided at the other end of the first conductor in the axial direction and disposed in the tubular body,
the second conductor includes a second insertion portion disposed in the tubular body,
the tubular body includes:
a spring portion configured in a spiral shape along a peripheral surface of the tubular body; and
a first body portion connected to one side in the axial direction of the spring portion,
the first insertion portion is fixed to the first body portion, and
an end side notch extending along the axial direction from an end surface on one side in the axial direction of the tubular body is provided on a peripheral surface of the first body portion,
wherein one end portion in the axial direction of the second insertion portion is in contact with the first body portion; and
a support member that supports the plurality of the contact terminals.
